(19) United States
(12) Patent Application Publication
(10) Pub. No.: US 2025/0336748 A1
(43) Pub. Date: Oct. 30, 2025

(54) SEMICONDUCTOR CHIP

(71) Applicant: Samsung Electronics Co., Ltd., Suwon-si (KR)

(72) Inventors: Daewoong HEO, Suwon-si (KR); Ieun KIM, Suwon-si (KR); Haemin PARK, Suwon-si (KR)

(73) Assignee: Samsung Electronics Co., Ltd., Suwon-si (KR)

(21) Appl. No.: 18/975,216

(22) Filed: Dec. 10, 2024

(30) Foreign Application Priority Data
Apr. 24, 2024 (KR) 10-2024-0054825

(51) Int. Cl. H01L 23/31; H01L 23/00; H01L 23/29; H01L 23/544

(52) U.S. Cl. CPC H01L 23/3192; H01L 23/291; H01L 23/293; H01L 23/3171; H01L 23/544; H01L 24/48; H01L 2223/54426; H01L 2224/48145; H01L 2224/48227; H01L 2224/48996; H01L 2924/386

(57) ABSTRACT

A semiconductor chip includes a semiconductor substrate including a die region, and a peripheral region surrounding the die region; a device layer on the die region, the device layer including semiconductor devices and wiring layers; a peripheral protective layer surrounding the device layer on the peripheral region; and connection pads on an upper surface of the device layer and adjacent to one side of the upper surface of the device layer, wherein a side surface of the semiconductor substrate adjacent to the one side of the upper surface of the device layer includes protruding portions located at both corners and a recess surface indented into the die region between the protruding portions.

### CROSS-REFERENCE TO RELATED APPLICATION(S)

This application claims benefit of and priority to Korean Patent Application No. 10-2024-0054825 filed on Apr. 24, 2024 in the Korean Intellectual Property Office, the disclosure of which is incorporated herein by reference in its entirety.

### BACKGROUND

The present inventive concepts relate to semiconductor chips and methods for manufacturing the same.

Recently, there has been a demand for increased performance and increased capacity of a semiconductor package mounted in an electronic device. Researchers are continuing to reduce a size of the package in order to embed a greater number of chips. Accordingly, research is being conducted into a structure of a semiconductor chip and a method of manufacturing the semiconductor chip to prevent defects in a bonding wire connecting the semiconductor chip and a semiconductor package substrate.

### SUMMARY

An aspect of the present inventive concepts is to provide a semiconductor chip having improved reliability.

According to some aspects of the present inventive concepts, a semiconductor chip includes a semiconductor substrate including a die region, and a peripheral region surrounding the die region; a device layer on the die region, the device layer including semiconductor devices and wiring layers; a peripheral protective layer surrounding the device layer on the peripheral region; and connection pads on an upper surface of the device layer and adjacent to one side of the upper surface of the device layer, wherein a side surface of the semiconductor substrate adjacent to the one side of the upper surface of the device layer includes protruding portions located at both corners and a recess surface indented into the die region between the protruding portions.

According to some aspects of the present inventive concepts, a semiconductor chip includes a semiconductor substrate including an active surface and a non-active surface opposite to each other; a device layer disposed on the active surface and having a rectangular parallelepiped shape; a peripheral protective layer surrounding the device layer on the active surface, the peripheral protective layer including a first film on the active surface and a second film on the first film; and connection pads disposed adjacent to one side surface of the device layer on an upper surface of the device layer, wherein the first film has a first plane thickness between at least one side surface of the first film and at least one side surface of the device layer, and the first film surrounds the device layer, and at least a portion of the first film, covering the one side surface of the device layer, has a second plane thickness, between a side surface of the first film and a side surface of the device layer, smaller than the first plane thickness.

According to some aspects of the present inventive concepts, a semiconductor chip includes a semiconductor substrate having an active surface and a non-active surface opposite to each other, the semiconductor substrate including side surfaces; a device layer on the active surface, the device layer including semiconductor devices and wiring layers; and a peripheral protective layer surrounding the device layer on the active surface, wherein at least one of the side surfaces of the semiconductor substrate has protruding surfaces intersecting the other side surfaces of the semiconductor substrate at both corners, a recess surface indented toward the device layer between the protruding surfaces, and stepped surfaces connecting the protruding surfaces and the recess surface.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a perspective view illustrating a semiconductor chip according to some example embodiments.

FIG. 1B is a plan view illustrating a semiconductor chip according to some example embodiments.

FIG. 1C is a cross-sectional view illustrating a semiconductor chip according to some example embodiments.

FIG. 2 is an enlarged side view illustrating a portion of a semiconductor chip according to some example embodiments.

FIGS. 3 to 7 are plan views illustrating semiconductor chips according to some example embodiments.

FIG. 8A is a cross-sectional view illustrating a semiconductor package according to some example embodiments.

FIG. 8B is a plan view illustrating a semiconductor package according to some example embodiments.

FIGS. 9 and 10 are plan views illustrating semiconductor packages according to some example embodiments.

FIG. 11 is a perspective view illustrating a wafer structure according to some example embodiments.

FIGS. 12A, 13A, and 14A are enlarged plan views illustrating a process sequence illustrating a method of manufacturing a semiconductor chip according to some example embodiments.

FIGS. 12B, 13B, and 14B are enlarged cross-sectional views illustrated according to a process sequence illustrating a method of manufacturing a semiconductor chip according to some example embodiments.

FIG. 15 is a perspective view illustrating a process for attaching a protective sheet to a wafer structure according to some example embodiments.

FIG. 16 is an enlarged cross-sectional view illustrating a method of manufacturing a semiconductor chip according to some example embodiments.

FIG. 17 is a perspective view illustrating a process of irradiating a laser into the inside of a semiconductor substrate according to some example embodiments.

FIGS. 18 and 19 are enlarged cross-sectional views illustrated according to a process sequence illustrating a method of manufacturing a semiconductor chip according to some example embodiments.

### DETAILED DESCRIPTION

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

Hereinafter, some example embodiments of the present inventive concepts will be described with reference to the accompanying drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except in which otherwise indicated.

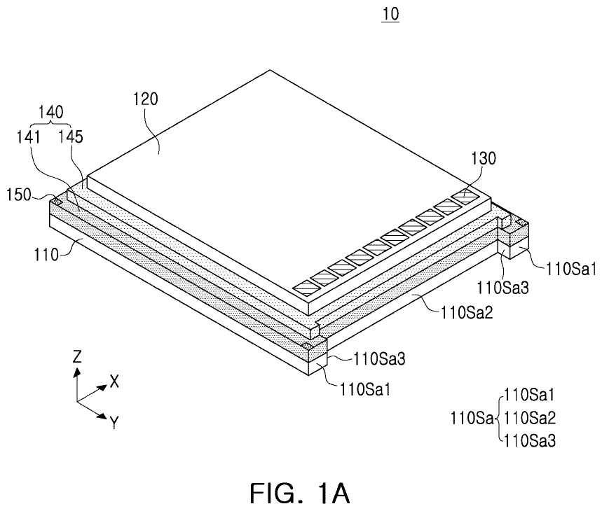

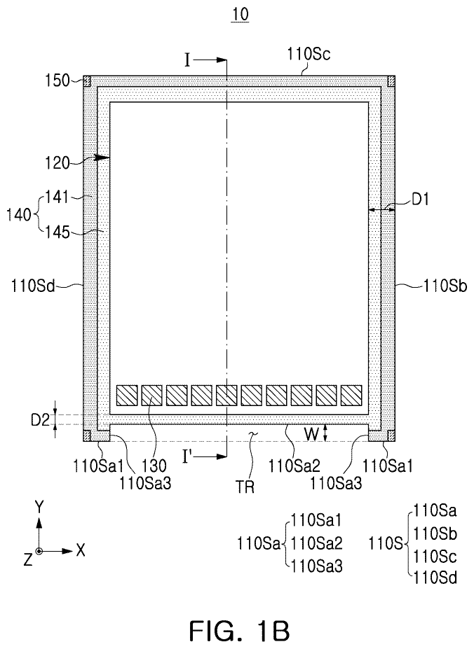

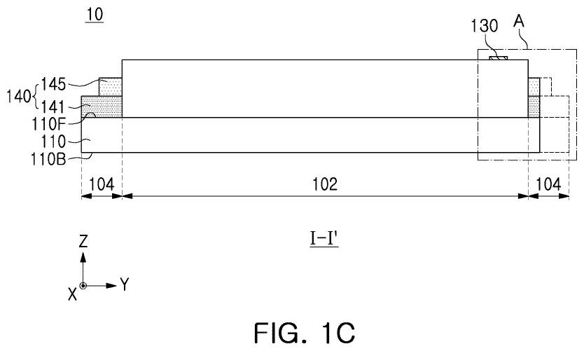

FIG. 1A is a perspective view illustrating a semiconductor chip according to some example embodiments.

FIG. 1B is a plan view illustrating a semiconductor chip according to some example embodiments.

FIG. 1C is a cross-sectional view illustrating a semiconductor chip according to some example embodiments. FIG. 1C schematically illustrates a cross-section of the semiconductor chip 10 of FIG. 1B, taken along line I-I′. In FIG. 1B, components that a device layer 120 may include will be omitted for convenience of explanation.

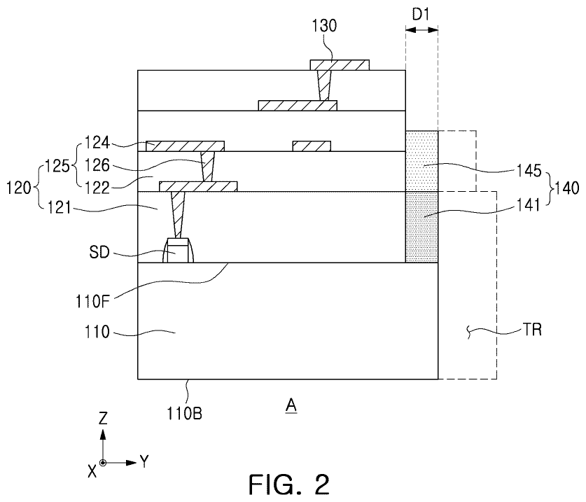

FIG. 2 is an enlarged side view illustrating a portion of a semiconductor chip according to some example embodiments. FIG. 2 schematically illustrates configurations that a device layer 120 may include.

Referring to FIGS. 1A to 2, a semiconductor chip 10 may include a semiconductor substrate 110, a device layer 120, connection pads 130, and a peripheral protective layer 140. The semiconductor chip 10 may further include a residual alignment key 150.

The semiconductor substrate 110 may include an opposing active surface 110F and a non-active surface 110B located opposite to the active surface 110F. The device layer 120 including semiconductor devices SD and an interconnection structure 125, and the peripheral protective layer 140 surrounding the device layer 120 may be disposed on the active surface 110F. The semiconductor substrate 110 may include a die region 102 on which the device layer 120 is disposed, and a peripheral region 104 surrounding the die region 102 and on which the peripheral protective layer 140 is disposed. The peripheral region 104 may be a region constituting a scribe lane in a wafer structure, or may be a residual region remaining after cutting individual chips. The peripheral region 104 may have a first width D1, and may surround the die region 102, and a portion in which a trench TR is formed may have a second width D2, smaller than the first width D1 and may cover one side surface of the die region 102. The first width D1 may be 5 μm to 50 μm or 20 μm to 30 μm, but the present inventive concepts are not limited thereto. The second width D2 may be smaller than the first width D1, and may have a size of 5 μm to 30 μm, 0.5 μm to 20 μm, or 1 μm to 10 μm, but the present inventive concepts are not limited thereto. The second width D2 may also be defined as a distance on a plane between the die region 102 and a recess surface 110Sa2.

The semiconductor substrate 110 may include side surfaces connecting the active surface 110F and the non-active surface 110B. The semiconductor substrate 110 may include first to fourth side surfaces 110Sa, 110Sb, 110Sc, and 110Sd. The first side surface 110Sa may include protruding surfaces 110Sa1 located at both corners, a recess surface 110Sa2 located between the protruding surfaces 110Sa1 and further inwardly than the protruding surfaces 110Sa1, and stepped surfaces 110Sa3 connecting the protruding surfaces 110Sa1 and the recess surface 110Sa2. These may be referred to as a first recess surface 110Sa2, first protruding surfaces 110Sa1, and first stepped surfaces 110Sa3, respectively. The protruding surfaces 110Sa1 may intersect the second side surface 110Sb and the fourth side surface 110Sd, which intersect the first side surface 110Sa. The protruding surfaces 110Sa1 may be referred to as a protruding portion, a non-etched surface, or the like. The recess surface 110Sa2 may be indented toward the die region 102. In some example embodiments, the recess surface 110Sa2 may be parallel to one side surface of a device layer 120 adjacent thereto. For example, the recess surface 110Sa2 may be parallel to third side surface 110Sc. In some example embodiments, the recess surface 110Sa2 may be parallel to the protruding surfaces 110Sa1. Based on FIG. 1B, a length of the recess surface 110Sa2 extending in an X-direction may be substantially the same as a width of the device layer 120 in the X-direction, or may be larger or smaller than the width of the device layer 120, depending on an example embodiment. An indentation distance W of the recess surface 110Sa2 or an etch width W of the trench TR may be 5 μm to 50 μm, 5 μm to 30 μm, or 10 μm to 20 μm, but the present inventive concepts are not limited thereto. The recess surface 110Sa2 may be referred to as an indented surface, an etch surface, etc. The stepped surfaces 110Sa3 may connect and intersect the protruding surfaces 110Sa1 and the recess surfaces 110Sa2. In some example embodiments, the stepped surfaces 110Sa3 may be perpendicular to the protruding surfaces 110Sa1, and may be parallel to the second side surface 110Sb and the fourth side surface 110Sd.

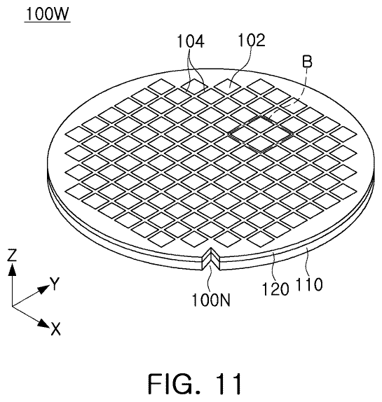

Originally, the semiconductor substrate 110 may have a rectangular parallelepiped shape (e.g., each surface of the semiconductor substrate 110 may have a parallelogram shape), but may be a structure in which the trench TR is formed in the first side surface 110Sa during a process such that the first side surface 110Sa has the protruding surface 110Sa1, the recess surface 110Sa2, and the stepped surfaces 110Sa3. Depending on the example embodiments of the manufacturing method, the trench TR may be formed before cutting individual semiconductor chips in a wafer structure stage, or may be formed through an additional etching process after cutting the individual semiconductor chips. A process of manufacturing the trench TR and the first recess surface 110Sa will be described in detail in the description with reference to FIG. 11 and below.

The semiconductor substrate 110 may include, for example, silicon. Alternatively, the semiconductor substrate 110 may include a semiconductor device such as germanium, or a compound semiconductor such as silicon carbide (SiC), gallium arsenide (GaAs), indium arsenide (InAs), and/or indium phosphide (InP). Alternatively, the semiconductor substrate 110 may have a silicon-on-insulator (SOI) structure. In some example embodiments, the semiconductor substrate 110 may include an impurity-doped well or an impurity-doped structure, which may be a conductive region. Additionally, the semiconductor substrate 110 may have various device isolation structures, such as a shallow trench isolation (STI) structure.

The device layer 120 may be disposed on the active surface 110F of the semiconductor substrate 110. The device layer 120 may include the semiconductor devices SD disposed on the active surface 110F, an interlayer insulating layer 121 disposed on the active surface 110F and covering the semiconductor devices SD, and an interconnection structure 125 disposed on the interlayer insulating layer 121 and connected to the semiconductor devices.

The semiconductor devices SD may be divided into a memory device and a logic device. The memory device may be a volatile memory device or a non-volatile memory device. For example, the volatile memory device may include a memory device such as a dynamic random access memory (DRAM), a static RAM (SRAM), a thyristor RAM (TRAM), a zero capacitor RAM (ZRAM), or a twin transistor RAM (TTRAM). In addition, the non-volatile memory device may include, for example, a memory device such as a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, a nano floating gate memory, a holographic memory, a molecular electronics memory, or an insulator resistance change memory.

The logic device may be implemented as, for example, a microprocessor, a graphics processor, a signal processor, a network processor, an audio codec, a video codec, an application processor, a system-on-chip, or the like, but the present inventive concepts are not limited thereto.

The interlayer insulating layer 121 may cover the semiconductor devices SD on the active surface 110F. The interlayer insulating layer 121 may be formed of a low-κ material. The low-κ material may be a material with a lower dielectric constant than silicon oxide, and when the low-κ material is used as the interlayer insulating layer 121 in the semiconductor device SD, it may be advantageous in realizing high integration and high speed of the semiconductor device SD due to improved insulating ability thereof. The interlayer insulating layer 121 may include, for example, silicon oxide doped with impurities, or an organic polymer. The interlayer insulating layer 121 may include, for example, SiOCH, SiCN, or a combination thereof.

The interconnection structure 125 may be disposed on the interlayer insulating layer 121, and may include an upper insulating layer 122, a metal interconnection 124, and a metal via 126. The interconnection structure 125 may have a multilayer (e.g., three-layer) interconnection structure in which the upper insulating layer 122 and the metal interconnection 124 are alternately arranged. Additionally, the metal interconnection 124 of each of the layers may include a plurality of metal vias 126 disposed in a direction, perpendicular to the active surface 110F of the semiconductor substrate 110 (e.g., Z-direction). For example, the metal interconnection 124 and the metal via 126 may be formed of a conductive material containing at least one of aluminum (Al), copper (Cu), nickel (Ni), tungsten W, platinum (Pt), or gold (Au). In some example embodiments, the metal interconnection 124 having a multilayer structure is illustrated as three layers, but the present inventive concepts are not limited thereto. Unlike the depicted example embodiments, the metal interconnection 124 may be formed as two layers, or four or more layers. The upper insulating layer 122 may cover the interconnection structure 125 on the interlayer insulating layer 121. The upper insulating layer 122 may include a plurality of insulating layers. In some example embodiments, the upper insulating layer 122 is illustrated as three layers, but the present inventive concepts are not limited thereto. Unlike some example embodiments, the upper insulating layer 122 may be formed as two layers, or four or more layers.

The connection pads 130 may be disposed on the device layer 120. The connection pads 130 may be arranged in parallel on one side of the device layer 120 adjacent to the first side surface 110Sa of the semiconductor substrate 110. The connection pads 130 may be connected to the metal interconnection 124 through the metal via 126. The connection pads 130 may include, for example, a ground pad, a power pad, an AC pad, a data pad, and a DC pad. The ground pad may be a pad providing a reference potential for circuit operation of the semiconductor chip 10. The power pad may be a pad supplying power for circuit operation. The AC pad may be a pad supplying AC power to the semiconductor chip 10 or receiving a signal for performing an AC test. The data pad may be a pad for inputting/outputting of a logic signal or data. The DC pad may be a pad measuring a potential level at a specific position of the semiconductor chip 10. The connection pads 130 may include a conductive material, and in some example embodiments, may include at least one of aluminum (Al), copper (Cu), or titanium (Ti), but the present inventive concepts are not limited thereto.

The peripheral protective layer 140 may be disposed surrounding the device layer 120 on the active surface 110F. The peripheral protective layer 140 may surround side surfaces of the device layer 120. The peripheral protective layer 140 may be disposed on the peripheral region 104 of the semiconductor substrate 110. The peripheral protective layer 140 was originally designed to cover the active surface 110F in a scribe lane of a wafer structure, but may be cut into individual semiconductor chips and may remain on the peripheral region 104. An upper surface of the peripheral protective layer 140 may be lower than an upper surface of the device layer 120, but the present inventive concepts are not limited thereto. In some example embodiments, the peripheral protective layer 140 may include a material, different from a material of the interlayer insulating layer 121 and a material of the upper insulating layer 122. The peripheral protective layer 140 may include a first film 141 and a second film 145.

The first film 141 may surround the device layer 120 on the active surface 110F. The first film 141 may completely cover the active surface 110F of the peripheral region 104 of the semiconductor substrate 110. At least a portion of side surfaces of the first film 141 may be coplanar with the side surfaces 110Sa, 110Sb, 110Sc, and 110Sd of the semiconductor substrate 110. The first film 141 may have a first plane thickness D1 (e.g., a thickness in the X direction between a side surface of the first film 141 and a side surface of the device layer 120), and may surround the device layer 120. A portion of the first film 141 disposed between the first recess surface 110Sa and the die region 102 may have a second plane thickness D2 (e.g., a thickness in the Y direction between the first recess surface 110Sa2 and a side surface of the device layer 120), smaller than the first plane thickness D1, and may cover the device layer 120. The first plane thickness D1 may be 5 μm to 50 μm or 20 μm to 30 μm, but the present inventive concepts are not limited thereto. The second plane thickness D2 may be smaller than the first plane thickness D1, and may have a size of 5 μm to 30 μm, 0.5 μm to 20 μm, or 1 μm to 10 μm, but the present inventive concepts are not limited thereto. The first film 141 may contain a material reducing generation of burrs that may occur when cutting individual semiconductor chips.

In some example embodiments, the first film 141 may include a material, different from a material of the semiconductor substrate 110. In some example embodiments, the first film 141 may include a material, different from a material included in the device layer 120. In some example embodiments, the first film 141 may include a material having a thermal expansion coefficient, higher than a thermal expansion coefficient of the material of the semiconductor substrate 110. The thermal expansion coefficient refers to a ratio between a temperature and thermal expansion of an object under a certain pressure, and a material having a relatively high thermal expansion coefficient may have a large degree of expansion or contraction in volume, depending on a change in temperature. In some example embodiments, the first film 141 may include an organic compound. In some example embodiments, the first film 141 may be integrated with the interlayer insulating layer 121 of the device layer 120. In this case, the first film 141 may be formed together with the interlayer insulating layer 121 in a process of forming the interlayer insulating layer 121 of the device layer 120.

The second film 145 may surround the device layer 120 on the first film 141. The second film 145 may cover a portion of an upper surface of the first film 141. A planar area of the second film 145 may be smaller than a planar area of the first film 141 (e.g., the surface area of an upper surface of the second film 145 may be smaller than a surface area of an upper surface of the first film 141). The second film 145 may cover a portion of the upper surface of the first film 141, adjacent to the device layer 120, and an edge of the upper surface of the first film 141 may be exposed. The second film 145 may include an insulating material, and may include a material in which it may be easy to form the trench TR. In some example embodiments, the second film 145 may include a material, different from a material of the semiconductor substrate 110. In some example embodiments, the second film 145 may include a material of which thermal expansion coefficient may be lower than thermal expansion coefficient of the semiconductor substrate 110. In some example embodiments, the second film 145 may include a material, different from a material of the first film 141. In some example embodiments, the second film 145 may include a material, different from a material of the interlayer insulating layer 121 and a material of the upper insulating layer 122 of the device layer 120. In some example embodiments, the second film 145 may include silicon oxide. The second film 145 may surround a side surface of the device layer 120, and an upper surface of the second film 145 may be located on a level, lower than a level of an upper surface of the device layer 120.

The remaining alignment keys 150 may be disposed in a corner portion of an upper surface of the peripheral protective layer 140. The corner portion refers to a vertex portion in which an upper surface and two side surfaces intersect. The remaining alignment keys 150 may be disposed in a corner portion of an upper surface of the first film 141 layer. The residual alignment keys 150 may exist in a configuration additionally disposed on the first film 141, but the present inventive concepts are not limited thereto, and a portion of the upper surface of the first film 141 may be etched, or may be marked on the upper surface. The remaining alignment keys 150 may be disposed at a position in which the peripheral region 104 intersects in a wafer structure stage, and may remain on the peripheral protective layer 140 after cutting individual semiconductor chips.

A semiconductor chip 10 according to some example embodiments may prevent or reduce in likelihood contacting a bonding wires that may be connected to the connection pads 130 with other components of the semiconductor chip 10 by including the trench TR by at least a portion of the side surfaces 110Sa, 110Sb, 110Sc, and 110Sd of the semiconductor substrate 110, and disposing the connection pads 130 adjacent to a side surface of the semiconductor substrate in which the trench TR is formed on an upper surface of the device layer 120. Additionally, since the second film 145 may include an insulating material, current leakage may be prevented or reduced in likelihood even in the case that the second film 145 contacts the bonding wire. The first film 141 may minimize or reduce the occurrence of burrs in the semiconductor substrate 110 and thus prevent or reduce in likelihood the occurrence of warping or the like of the semiconductor substrate 110. Therefore, since a margin of the bonding wire may be secured, defects that may occur when the bonding wires contact each other may be prevented or reduced in likelihood, and a semiconductor chip having improved reliability may be provided.

Additionally, reliability and integration of a semiconductor package including a semiconductor chip 10 according to some example embodiments may be improved.

In the following description, descriptions overlapping those described with reference to FIGS. 1A to 2 will be omitted.

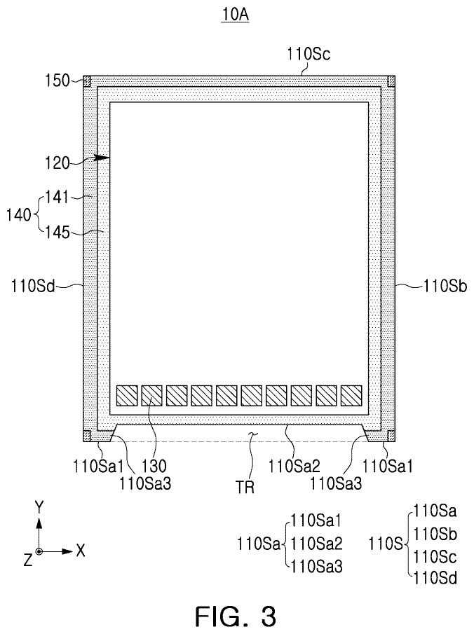

FIGS. 3 to 7 are plan views illustrating semiconductor chips according to some example embodiments.

Referring to FIG. 3, unlike the semiconductor chip 10 of FIGS. 1A to 2, a semiconductor chip 10A may have a trapezoidal planar shape of a trench TR. Stepped surfaces 110Sa3 may become closer to each other toward a device layer 120. In some example embodiments, a length of a recess surface 110Sa2 extending in the first direction (e.g., X-direction) may be equal to or smaller than a width of the device layer 120 in the first direction, and a distance between the protruding surfaces 110Sa1 in the first direction may be equal to or greater than the width of the device layer 120 in the first direction. In some example embodiments, the length of the recess surface 110Sa2 extending in the first direction may be greater than the width of the device layer 120 in the first direction.

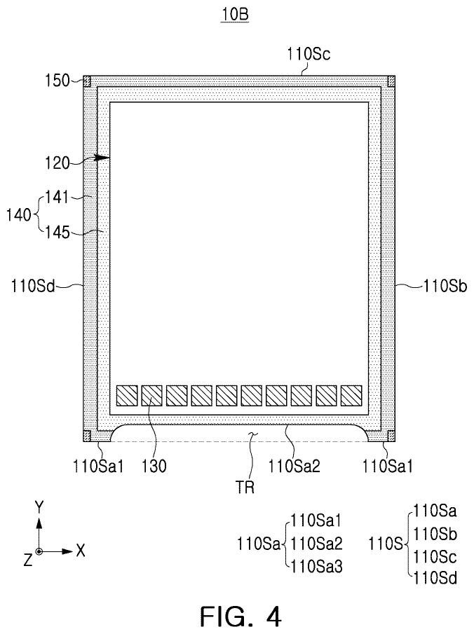

Referring to FIG. 4, a semiconductor chip 10B may have a semi-elliptical planar shape of a trench TR, and a recess surface 110Sa2 may have a concave curvature. Therefore, unlike the semiconductor chip 10 of FIGS. 1A to 2, a stepped surface 110Sa3 may not exist.

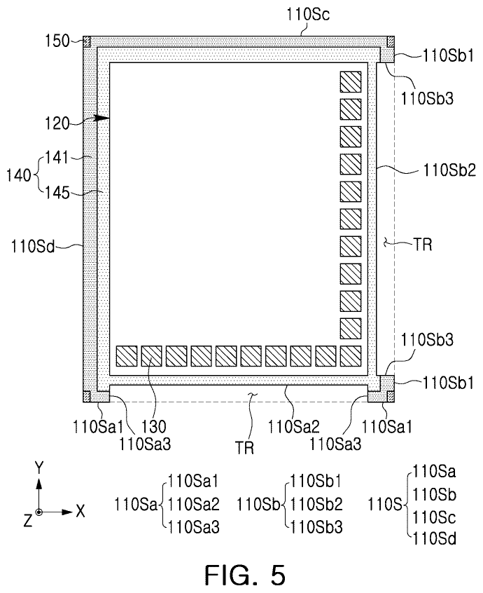

Referring to FIG. 5, unlike the semiconductor chip 10 of FIGS. 1A to 2, in a semiconductor chip 10C, a trench TR may be formed in plural. The trench TR may be formed not only on a first side surface 110Sa but also on a second side surface 110Sb. The second side surface 110Sb intersecting the first side surface 110Sa may include second protruding surfaces 110Sb1, a second recess surface 110Sb2, and second stepped surfaces 110Sb3. Connection pads 130 may be arranged side by side, on one side of an upper surface of a device layer 120, adjacent to the first side surface 110Sa, and one side of the upper surface of the device layer 120, adjacent to the second side surface 110Sb, respectively. In some example embodiments, the first side surface 110Sa and the second side surface 110Sb may be recessed while the third side surface 110Sc and the fourth side surface 110Sd may not be recessed.

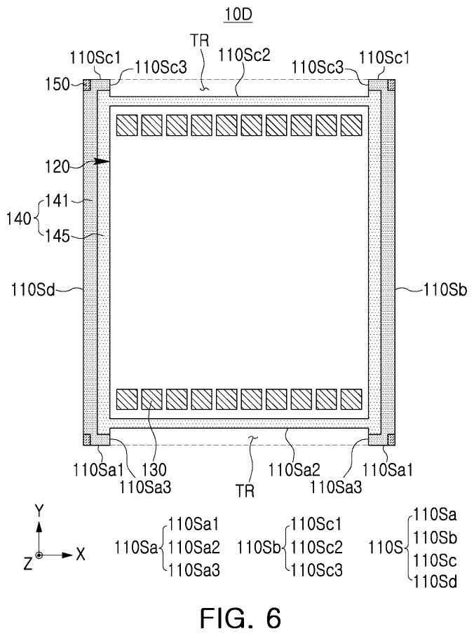

Referring to FIG. 6, unlike the semiconductor chip 10 of FIGS. 1A to 2, in a semiconductor chip 10D, a trench TR may be formed in plural. The trench TR may be formed on a first side surface 110Sa and a third side surface 110Sc, opposite to each other. Therefore, the first side surface 110Sa may include first protruding surfaces 110Sa1, a first recess surface 110Sa2, and first stepped surfaces 110Sa3, and the third side surface 110Sc may include third protruding surfaces 110Sc1, a third recess surface 110Sc2, and third stepped surfaces 110Sc3. Connection pads 130 may be arranged side by side, on one side of an upper surface of a device layer 120, adjacent to the first side surface 110Sa, and one side of the upper surface of the device layer 120, adjacent to the third side surface 110Sc, respectively. In some example embodiments, the first side surface 110Sa and the third side surface 110Sc may be recessed and the second side surface 110Sb and the fourth side surface 110Sd may not be recessed.

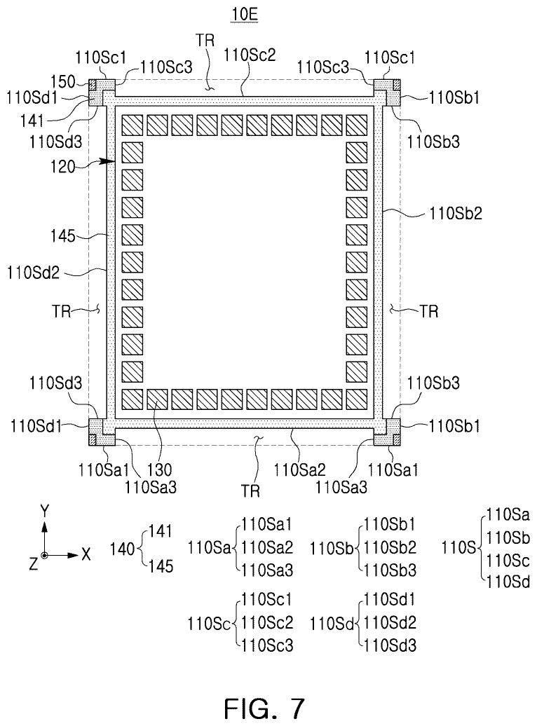

Referring to FIG. 7, unlike the semiconductor chip 10 of FIGS. 1A to 2, in a semiconductor chip 10E, a trench TR may be formed in all side surfaces 110S. Therefore, a first side surface 110Sa may include first protruding surfaces 110Sa1, a first recess surface 110Sa2, and first stepped surfaces 110Sa3, a second side surface 110Sb may include second protruding surfaces 110Sb1, a second recess surface 110Sb2, and second stepped surfaces 110Sb3, a third side surface 110Sc may include third protruding surfaces 110Sc1, a third recess surface 110Sc2, and third stepped surfaces 110Sc3, and a fourth side surface 110Sd may include fourth protruding surfaces 110Sd1, a fourth recess surface 110Sd2, and fourth stepped surfaces 110Sd3. Connection pads 130 may be arranged on an upper surface of a device layer 120, adjacent to each side surface.

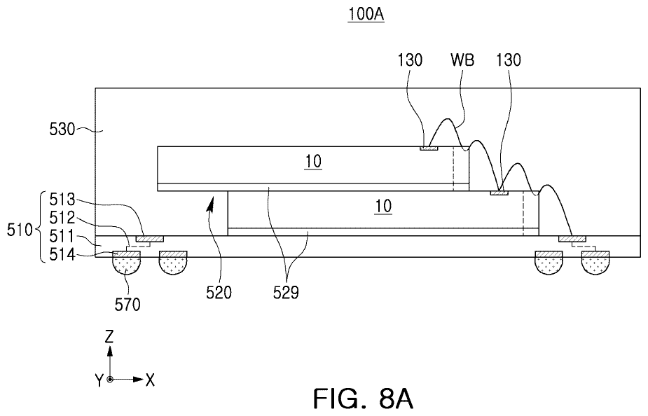

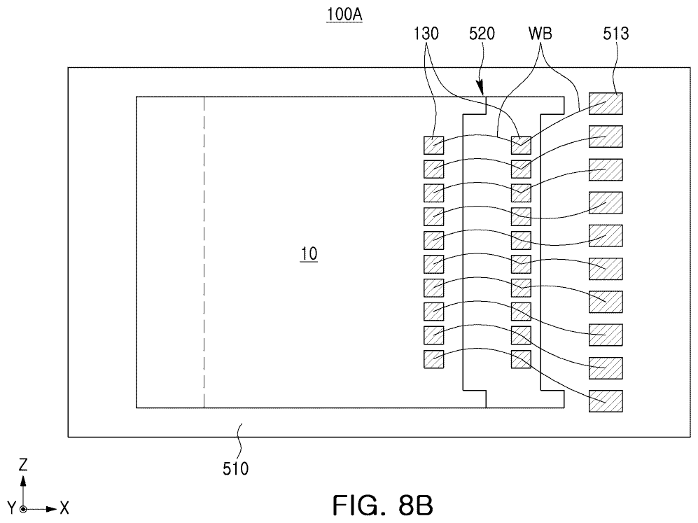

In some example embodiments of FIGS. 5 to 7, the connection pads 130 are illustrated to be arranged side by side on one side in which the trench TR is formed. Therefore, when mounting a semiconductor chip on a semiconductor package and connecting a bonding wire (see FIGS. 8A to 10), the bonding wire WB connected to the connection pads 130 may be configured to extend between the trenches TR. Arrangement between the connection pads 130 and the trench TR is not limited thereto, and depending on some example embodiments, the connection pads 130 may be arranged side by side on the side in which the trench TR is not formed, or may be formed in the trench TR may also be formed on a side surface in which the connection pads 130 is not disposed.

Features of the semiconductor chips described with reference to FIGS. 1A to 7 may be combined or modified within a compatible range.

FIG. 8A is a cross-sectional view illustrating a semiconductor package according to some example embodiments.

FIG. 8B is a plan view illustrating a semiconductor package according to some example embodiments.

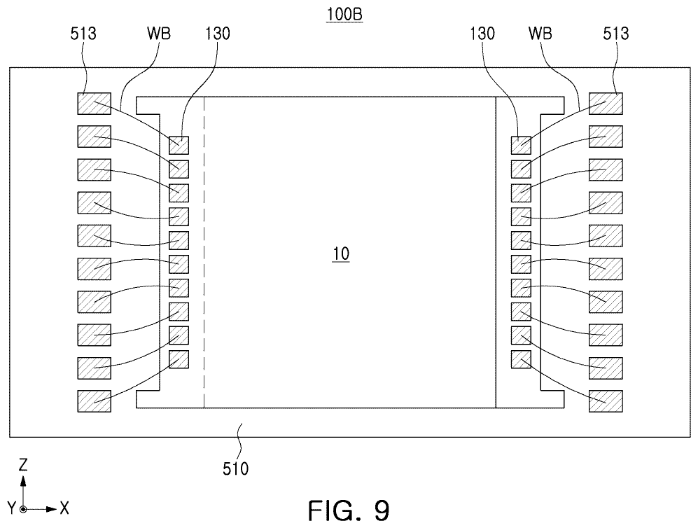

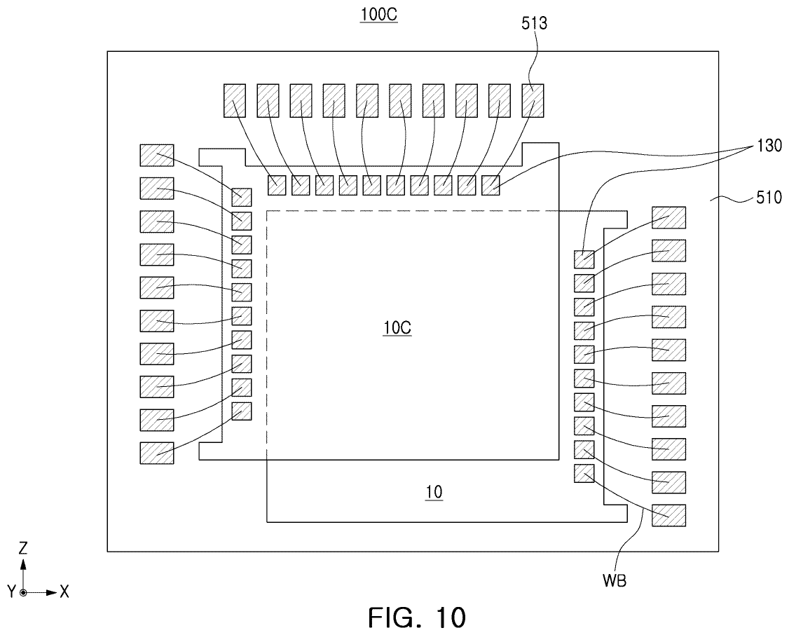

FIGS. 9 and 10 are plan views illustrating semiconductor packages according to some example embodiments.

FIGS. 8A to 10 illustrate some example embodiments of a semiconductor package on which a semiconductor chip of the present inventive concepts is mounted.

Referring to FIGS. 8A and 8B, a semiconductor package 100A may include a package substrate 510, a plurality of semiconductor chips 520, an encapsulant 530, and external connection conductors 570. The package substrate 510 may include an insulating layer 511, a wiring circuit 512, upper pads 513, and lower pads 514. The package substrate 510 may be a substrate for semiconductor package including a printed circuit board (PCB), a ceramic substrate, a glass substrate, a tape wiring substrate, or the like.

The insulating layer 511 may include an insulating resin. The insulating resin may be a thermosetting resin such as an epoxy resin, a thermoplastic resin such as polyimide, or a resin in which an inorganic filler or/and a glass fiber (a glass fiber, a glass cloth, or a glass fabric) are impregnated into these resins, such as a prepreg, an Ajinomoto build-up film (ABF), an FR-4, or bismaleimide triazine (BT). The insulating resin may include a photosensitive resin such as a photoimageable dielectric (PID) resin. For example, when the package substrate 510 is a PCB substrate, the insulating layer 511 may be a core insulating layer (e.g., prepreg) of a copper clad laminate. The insulating layer 511 may have a form in which a large number of insulating layers are stacked in a vertical direction (e.g., Z-axis direction), and depending on a process, a boundary between the first insulating layers at different levels may be unclear.

The wiring circuit 512 may be disposed in the insulating layer 511, and may form an electrical path in the package substrate 510. The wiring circuit 512 may include at least one metal of copper (Cu), aluminum (Al), nickel (Ni), silver (Ag), gold (Au), platinum (Pt), tin (Sn), lead (Pb), and titanium (Ti), chromium (Cr), palladium (Pd), indium (In), zinc (Zn), or Carbon©), or an alloy formed of two or more metals. The wiring circuit 512 may be provided as a plurality of wiring circuits 512 located on different levels between insulating layers 511.

The upper pads 513 may be disposed on an upper surface of the insulating layer 511, and the lower pads 514 may be disposed on a lower surface of the insulating layer 511. The upper pads 513 and the lower pads 514 may be electrically connected through the wiring circuit 512. The upper pads 513 may be electrically connected to the plurality of semiconductor chips 520 through connection structures on the insulating layer 511, and the lower pads 514 may be electrically connected to a plurality of external connection conductors 570 below the insulating layer 511. The upper pads 513 and the lower pads 514 may include the same material as the wiring circuit, but the present inventive concepts are not limited thereto. In some example embodiments, the upper pads 513 may include at least one metal of copper (Cu), nickel (Ni), or gold (Au), or an alloy formed of two or more metals, but the present inventive concepts are not limited thereto.

In some example embodiments, the plurality of semiconductor chips 520 may include a semiconductor chip 10, as described with reference to FIGS. 1A to 2. The plurality of semiconductor chips 520 may be stacked in a direction, perpendicular to an upper surface of the package substrate 510. The plurality of semiconductor chips 520 may be attached to each other by an adhesive film 529 (e.g., DAF). In some example embodiments, a structure in which two semiconductor chips are stacked is illustrated, but the number of semiconductor chips to be stacked is not limited thereto, and a structure of three or four or more layers may be provided. Depending on some example embodiments, a structure in which one semiconductor chip is mounted may be provided. The plurality of semiconductor chips 520 may overlap each other in a direction, perpendicular to the upper surface of the package substrate 510 (e.g., Z-direction). The plurality of semiconductor chips 520 may be stacked in an offset manner in a second direction (e.g., X-direction) to be adjacent to one side, but the present inventive concepts are not limited thereto. In some example embodiments, the plurality of semiconductor chips 520 may not be aligned side by side, but may be arranged in a zigzag manner. The plurality of semiconductor chips 520 may be arranged in a staircase manner in which a portion of each of the upper surfaces thereof is exposed from other semiconductor chips. In some example embodiments, a portion of the plurality of semiconductor chips 520 may be arranged to overlap in a vertical direction. Referring to FIGS. 1A to 2 together, the plurality of semiconductor chips 520 may be stacked such that recess surface 110Sa2 face the same direction, respectively. For example, the plurality of semiconductor chips 520 may be stacked such that the recess surface 110Sa2 faces the first direction (e.g., X-direction), respectively.

A bonding wire WB may connect connection pads 130 and the upper pads 513. The bonding wire WB may extend between trenches TR of the semiconductor chip 10. As the semiconductor chip 10 includes a trench TR, and the bonding wire WB connects the connection pads 130 and the upper pads 513 in a direction in which the trench TR is formed, contact defects between the bonding wire WB and the semiconductor chip 10, or contact defects that may occur between the bonding wires WB may be prevented or reduced in likelihood. Therefore, a semiconductor package having improved reliability may be manufactured.

The encapsulant 530 may seal at least a portion of the plurality of semiconductor chips 520 on the upper surface of the package substrate 510. The sealing material 530 is, for example, a thermosetting resin such as an epoxy resin, a thermoplastic resin such as polyimide, or a prepreg in which an inorganic filler or the like is impregnated into these resins, an ABF, an FR-4, BT, an epoxy molding compound (EMC).

The external connection conductors 570 may be disposed on the lower surface of the package substrate 510, and may be electrically connected to the wiring circuit 512 and the lower pads 514. The external connection conductors 570 may physically and/or electrically connect the semiconductor package 100A to an external device. The external connection conductors 570 may include a conductive material, and may have a ball shape, a pin shape, or a lead shape. For example, the external connection conductors 570 may be solder balls.

Hereinafter, in the description referring to FIGS. 9 and 10, contents overlapping the description referring to FIGS. 8A and 8B will be omitted.

Referring to FIG. 9 together with FIGS. 1A to 2, in a semiconductor package 100B, semiconductor chips 520, stacked vertically, may be stacked such that trenches TR respectively included in semiconductor chips 10 face different directions. A semiconductor chip 10 located in an upper portion may be directly connected to upper pads 513 by a bonding wire WB. Since contact defects of the bonding wire WB is prevented by the trenches TR included in the semiconductor chips 10, an upper end of the bonding wire WB may be disposed on a lower level, and the upper pads 513 connected to the bonding wire WB may be disposed closer to the semiconductor chip. This may enable miniaturization of the semiconductor package.

Referring to FIG. 10 together with FIGS. 1A to 7, in a semiconductor package 100C, semiconductor chips 520 to be stacked may be variously stacked with the semiconductor chips of FIGS. 1A to 7. In some example embodiments, it is illustrated that semiconductor chips mounted in a lower portion are the semiconductor chips 10 of FIGS. 1A to 2, and semiconductor chips stacked in an upper portion are the semiconductor chips 10C of FIG. 5. The semiconductor chips stacked on the upper portion may include a plurality of trenches TR, and a bonding wire WB may be disposed between each of the trenches TR. Due to a trench TR structure, an upper end of the bonding wire WB may be disposed on a lower level, and upper pads 513 connected to the bonding wire WB may be disposed closer to the semiconductor chip. This may enable miniaturization of the semiconductor package.

Hereinafter, FIGS. 11 to 19 may be drawings illustrated according to a process sequence illustrating a method of forming individual semiconductor chips from a wafer structure stage. Although FIGS. 11 to 19 illustrate processes of manufacturing the semiconductor chips 10 of FIGS. 1A to 2, as a manufacturing process is modified, the semiconductor chips of FIGS. 3 to 7 may be manufactured. Drawings written with the same number can be understood as drawings illustrating the same manufacturing operation. In each of the operations, redundant explanations will be omitted.

FIG. 11 is a perspective view illustrating a wafer structure according to some example embodiments.

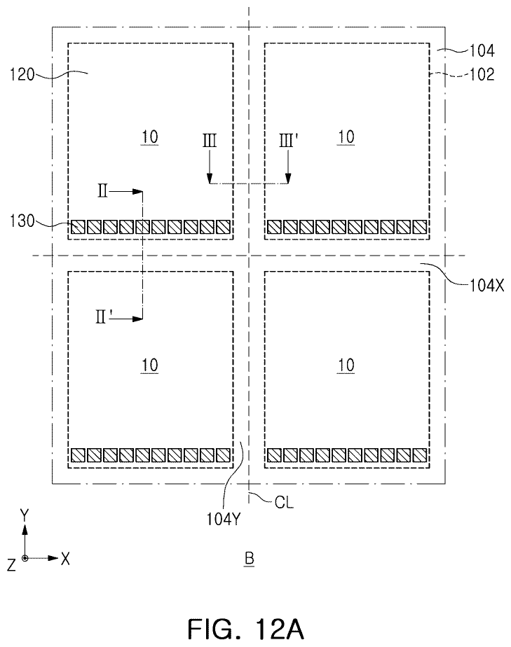

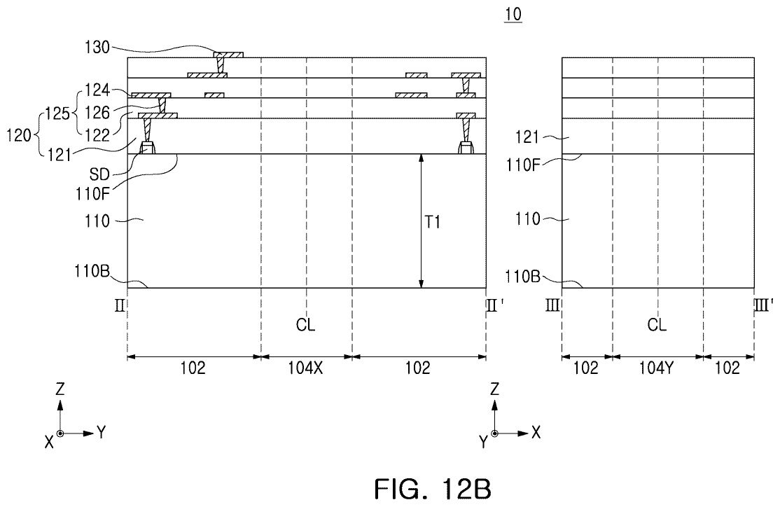

FIGS. 12A, 13A, and 14A are enlarged plan views illustrating a process sequence illustrating a method of manufacturing a semiconductor chip according to some example embodiments.

FIGS. 12B, 13B, and 14B are enlarged cross-sectional views illustrated according to a process sequence illustrating a method of manufacturing a semiconductor chip according to some example embodiments.

Referring to FIGS. 11 and 12A and 12B, a wafer structure 100W may include a semiconductor substrate 110 having an active surface 110F and a non-active surface 110B located opposite to the active surface 110F, and a device layer 120 disposed on the active surface 110F of the semiconductor substrate 110.

The wafer structure 100W may have a notch 100N in one region of a corner that may be used as a reference point for wafer alignment. The device layer 120 may include die regions 102 and a peripheral region 104. In this case, the die regions 102 and the peripheral region 104 may also be used as a term extending to the semiconductor substrate 110 in a direction, perpendicular to the active surface 110F (e.g., Z-direction), to distinguish the wafer structure 100W (see FIG. 12B).

The semiconductor substrate 110 may be a circular wafer having a constant first thickness T1. For example, the semiconductor substrate 110 may be a silicon wafer. Without being limited thereto, the semiconductor substrate 110 may be a wafer of a semiconductor element such as germanium, or a wafer of a compound semiconductor such as silicon carbide (SiC), gallium arsenide (GaAs), indium arsenide (InAs), and/or indium phosphide (InP).

When the first thickness T1 of the semiconductor substrate 110 is too thin, mechanical strength thereof may be insufficient, and when the first thickness T1 is too thick, a time period required for subsequent grinding increases to reduce productivity of the semiconductor chip. For example, the first thickness T1 of the semiconductor substrate 110 may range from about 0.1 mm to 1 mm.

As described above, a device layer having a plurality of integrated circuit regions (102) may be formed on the active surface 110F of the semiconductor substrate 110. The plurality of integrated circuit regions (102) may be separated from each other, together with the semiconductor substrate 110, in a subsequent process, and may be provided as semiconductor chips (e.g., FIGS. 1 to 7). The plurality of integrated circuit regions (102) may include a plurality of semiconductor devices SD.

Each of the die regions 102 may be arranged to be isolated from each other by the peripheral region 104. The peripheral region 104 may be referred to as a scribe lane. The peripheral region 104 may be formed by intersecting a portion 104X extending in a row direction (for example, X-direction) and a portion 104Y extending in a column direction (for example, Y-direction). The peripheral region 104 may be in the form of a straight lane having a constant width. As illustrated in FIG. 11, the die regions 102 may be arranged in a plurality of rows and a plurality of columns, with the peripheral region 104 interposed therebetween. Each of the die regions 102 may be surrounded by the peripheral region 104, and may be arranged to be spaced apart from each other.

As described above, the plurality of die regions 102 may be regions in which semiconductor devices SD for memory or logic functions are formed, and the peripheral region 104 may be a region in which the semiconductor devices are not formed. In some example embodiments, a plurality of semiconductor dummy devices may be arranged in the peripheral region 104.

On the active surface 110F in the die region 102, an interlayer insulating layer 121 covering the semiconductor devices SD, and an interconnection structure 125 disposed on the interlayer insulating layer 121 and connected to the semiconductor devices SD may be formed. The interlayer insulating layer 121 and an upper insulating layer 122 may cover not only the die region 102 but also the peripheral region 104.

Depending on some example embodiments, a dummy structure similar to the interconnection structure 125 may be formed in the peripheral region 104. For example, the dummy structure disposed in the peripheral region 104 may include multilayered dummy interconnections respectively corresponding to the metal interconnections 124, as well as the interlayer insulating layer 121 and the upper insulating layer 122. In some example embodiments, the peripheral region 104 may include a test pattern that may test the semiconductor device SD of the die region 102 or a redistribution layer for connection between test patterns.

Depending on some example embodiments, a material film having various functions, such as a passivation film, may be additionally formed on the upper insulating layer 122.

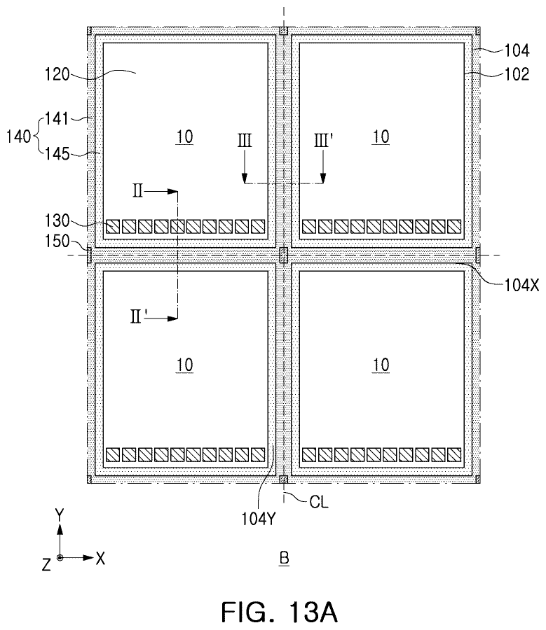

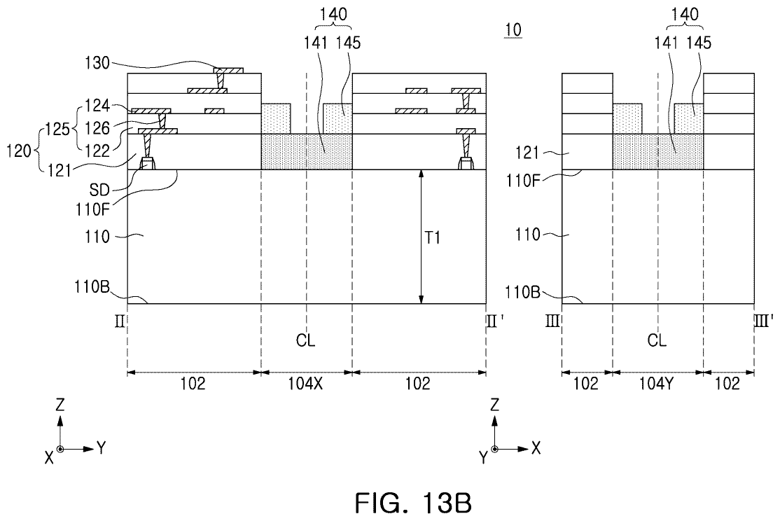

Referring to FIGS. 13A and 13B, an interlayer insulating layer 121 and an upper insulating layer 122 on a peripheral region 104 may be removed, and a first film 141 and a second film 145 may be formed in order. The first film 141 may remove the interlayer insulating layer 121 and the upper insulating layer 122 on the peripheral region 104 to expose an active surface 110F, and may be formed on the active surface 110F. In some example embodiments, after removing the interlayer insulating layer 121 and the upper insulating layer 122 in the peripheral region 104, a side surface of the interlayer insulating layer 121 and a side surface of the upper insulating layer 122, remaining in a die region 102, are illustrated as perpendicular to an upper surface of the active surface 110F, but the present inventive concepts are not limited thereto. For example, depending on an etching method, the side surface of the remaining interlayer insulating layer 121 and the side surface of the upper insulating layer 122 may be inclined. Depending on some example embodiments, a portion of the active surface 110F may be removed. The first film 141 may be formed of a material, different from a material of a semiconductor substrate 110, to minimize or reduce the generation of burrs that may occur when cutting individual semiconductor chips in the future. In some example embodiments, the first film 141 may be formed of a material having a thermal expansion coefficient, higher than a thermal expansion coefficient of a material of the semiconductor substrate 110. In some example embodiments, the first film 141 may include polysilicon. In some example embodiments, an upper surface of the first film 141 is illustrated to be on the same level as an upper surface of the interlayer insulating layer 121, but a thickness at which the first film 141 is formed is not limited thereto. Depending on some example embodiments, the upper surface of the first film 141 may be formed on a level, lower or higher than a level of the upper surface of the interlayer insulating layer 121. In some example embodiments, after removing only the upper insulating layer 122 in this operation, all or portion of the interlayer insulating layer 121 may be used as the first film 141. In this case, the first film 141 may include the same material as the interlayer insulating layer 121, and may be integrally formed.

The second film 145 may be formed on the upper surface of the first film 141 to expose a cutting line CL of the peripheral region 104. An upper surface of the second film 145 may be formed to be located on a level, lower than a level of an upper surface of the upper insulating layer 122. The second film 145 may be formed to entirely cover the upper surface of the first film 141, and the second film 145 may then be partially removed from around the cutting line CL. Depending on some example embodiments, the second film 145 may entirely cover the upper surface of the first film 141 in the peripheral region 104. The second film 145 may include an insulating material, and may include a material facilitating forming a trench TR in a subsequent process. In some example embodiments, the second film 145 may include a material, different from the material of the semiconductor substrate 110. In some example embodiments, the second film 145 may include a material, different from the material of the first film 141. In some example embodiments, the second film 145 may include a material, different from a material of the interlayer insulating layer 121 and a material of the upper insulating layer 122 of a device layer 120. In some example embodiments, the second film 145 may include silicon oxide.

An align key 150 may be a component for aligning a mask, and may be formed at a portion in which the cutting line CL intersects in the peripheral region 104. The align key 150 may be formed on the first film 141. The align key 150 may be a different component disposed on the first film 141, and depending on some example embodiments, may be a component formed by partially etching or marking the upper surface of the first film 141. The align key 150 may have a rectangular shape, but the present inventive concepts are not limited thereto, and may be formed in various shapes such as a triangle, a cross, a circle, or the like. Depending on a form in which the second film 145 is formed, the align key 150 may be formed on the second film 145.

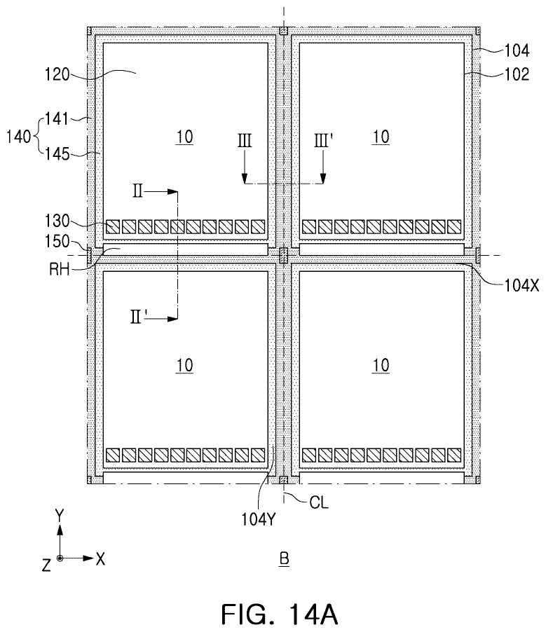

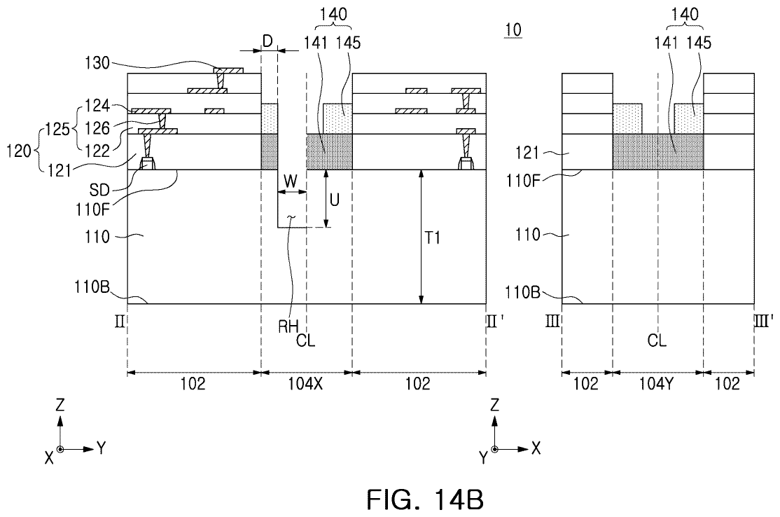

Referring to FIGS. 14A and 14B, a recess hole RH may be formed in a peripheral region 104. The recess hole RH may be used to form a trench TR, as described with reference to FIGS. 1A to 7, and may be formed in various manners, depending on a position, a size, a number, or the like of the trench TR to be desired. Depending on some example embodiments, when the trench TR is formed after cutting the individual semiconductor chip, a process of forming the recess hole RH may be omitted in this operation. The recess hole RH may be formed in the peripheral region 104 by penetrating a first film 141 and a second film 145 and partially removing an active surface 110F. The recess hole RH may be formed to extend along one side surface of a die region 102 in the peripheral region 104. A cross-sectional shape of the recess hole RH may not have only a rectangular shape, but also a trapezoidal shape, a semi-elliptical shape, or the like. When the recess hole RH has a trapezoidal shape, the semiconductor chip 10A of FIG. 3 may be manufactured, and when the recess hole RH has a semi-elliptical shape, the semiconductor chip 10B of FIG. 4 may be manufactured. The recess hole RH may be formed at a predetermined depth in a desired portion after aligning the mask using an align key 150. A recess depth U at which the semiconductor substrate 110 of the recess hole RH is removed may be formed so deep that a final semiconductor chip structure may include the trench TR. A recess width W and the recess depth U of the recess hole RH may be changed in various manners, depending on some example embodiments.

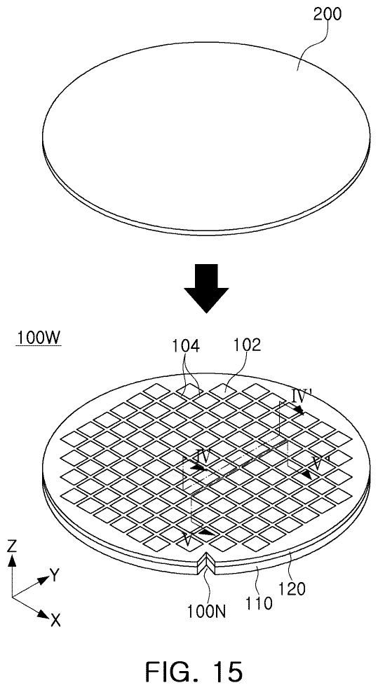

FIG. 15 is a perspective view illustrating a process for attaching a protective sheet to a wafer structure according to some example embodiments.

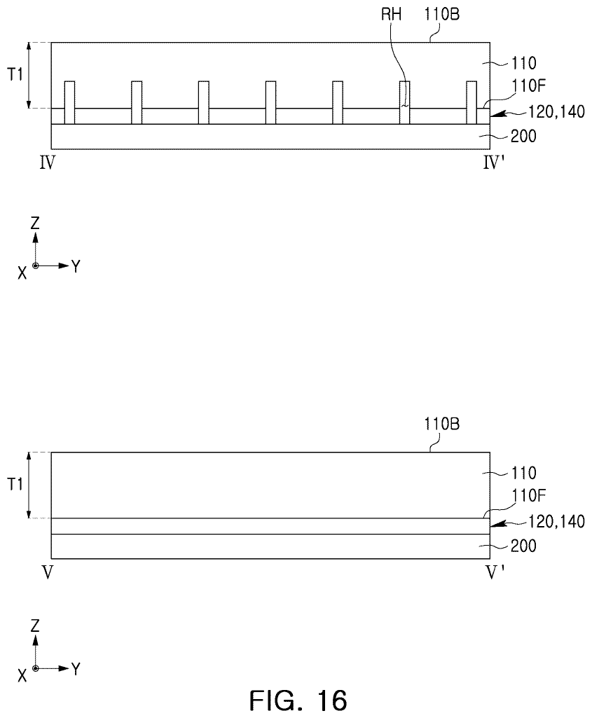

FIG. 16 is a cross-sectional view schematically illustrating a cross-section of a wafer structure to which a protective sheet is attached, taken along lines IV-IV′ and V-V′ of FIG. 5.

Referring to FIGS. 15 and 16, a protective sheet 200 may be attached to a device layer 120 and a peripheral protective layer 140 of a wafer structure 100W.

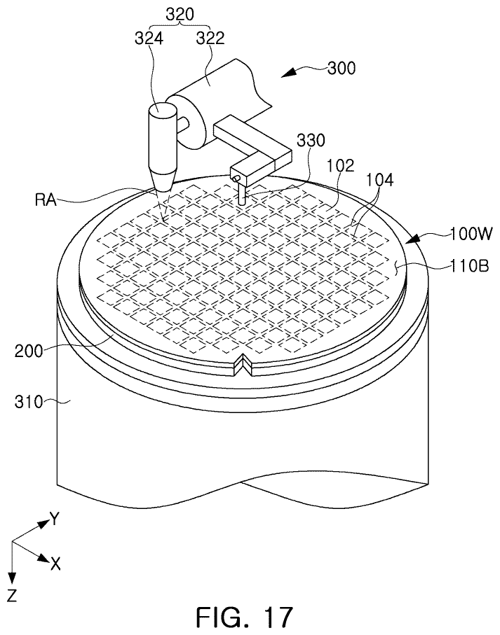

The wafer structure 100W may be arranged such that a surface to which the protective sheet 200 is attached faces a support such as a chuck table in a subsequent cutting process (see FIG. 17). The protective sheet 200 may protect the device layer 120 while the cutting process of the wafer structure 100W is performed. For example, the protective sheet 200 may be a polyvinylchloride (PVC)-based polymer sheet, and may be attached to the device layer 120 and the surrounding protective layer 140 using an acrylic resin-based adhesive. The acrylic resin-based adhesive may be applied in a thickness of about 2 μm to about 10 μm. The protective sheet 200 may have a thickness of about 60 μm to about 200 μm. In some example embodiments, the protective sheet 200 may be a die attach film (DAF). The protective sheet 200 may have a circular shape having a diameter, substantially equal to a diameter of the wafer structure 100W.

FIG. 17 is a perspective view illustrating a process of irradiating a laser into the inside of a semiconductor substrate according to some example embodiments.

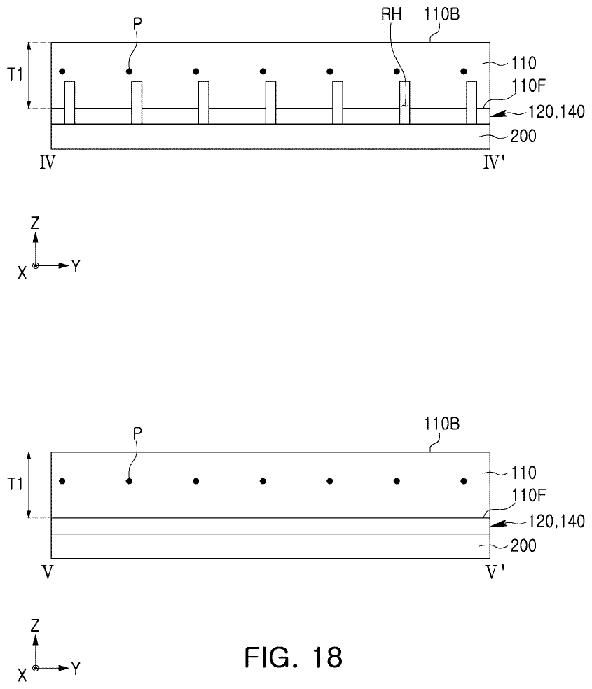

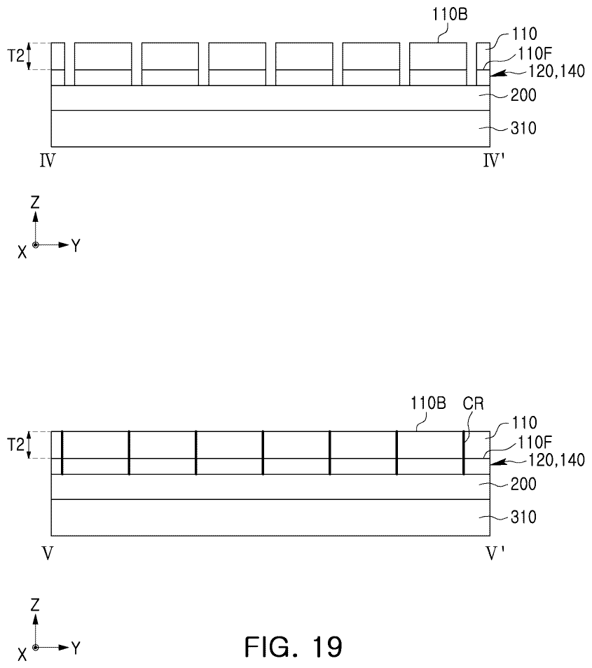

FIGS. 18 and 19 are enlarged cross-sectional views illustrated according to a process sequence illustrating a method of manufacturing a semiconductor chip according to some example embodiments. FIGS. 18 and 19 illustrate cross-sectional views corresponding to FIG. 16.

Referring to FIGS. 17 and 18, after attaching a protective sheet 200 to a wafer structure 100W, a laser RA having a wavelength that may be transparent to a semiconductor substrate 110 may be controlled to form a focusing point in a specific region in the semiconductor substrate 110. In this manner, the laser RA may be irradiated at regular intervals along a cutting line CL, to form a modified portion P along the cutting line CL at a certain depth in the semiconductor substrate 110. Formation of this modified portion P may be performed using a laser irradiation device 300.

The laser irradiation device 300 may include a chuck table 310 supporting the semiconductor substrate 110, a laser irradiation unit 320 for irradiating the laser RA to the semiconductor substrate 110 disposed on the chuck table 310, and an imaging unit 330 capturing an image of the semiconductor substrate 110 disposed on the chuck table 310. The chuck table 310 may be configured to suction and support the semiconductor substrate 110 using vacuum pressure, and move in a row direction (e.g., X-direction) and a column direction (e.g., Y-direction).

The laser irradiation unit 320 may be configured to irradiate a pulse laser from a concentrator 324 mounted on a front end portion of a cylindrical housing 322 arranged substantially horizontally. In addition, while the concentrator 324 radiates a pulse laser having a wavelength having transparency to the semiconductor substrate 110, the chuck table 310 and the concentrator 324 may move relative to each other at an appropriate speed.

The imaging unit 330 mounted on the other front end portion of the housing 322 constituting the laser irradiation unit 320 may be a conventional CCD imaging device that captures images using visible light. In other example embodiments, the imaging unit 330 may have an infrared irradiation unit for irradiating infrared rays to the semiconductor substrate 110, and an optical system for capturing the infrared rays irradiated by the infrared irradiation unit, and may be configured to include an infrared CCD imaging device for outputting an electrical signal corresponding to the infrared rays captured by the optical system.

The laser irradiation unit 320 may be aligned at the laser irradiation position, and may then irradiate the laser RA. The focusing point of the laser RA, e.g., the modified portion P, may be controlled to be located closer to an active surface 110F, as compared to a non-active surface 110B, of the semiconductor substrate 110. The laser RA emitted from the laser irradiation unit 320 may be intensively irradiated such that a portion of the semiconductor substrate 110 may be heated to a temperature of about 600° C. For example, an area of the semiconductor substrate 110 located at the focusing point of the laser RA may be partially melted by the laser RA.

The modified portion P may be located a certain distance away from the non-active surface 110B of the semiconductor substrate 110, and the modified portion P may be located closer to the active surface 110F. The laser may be light amplified by stimulated emission, and may be easily irradiated to a desired position. Using properties of the laser, the modified portion P may be formed at a desired position in the semiconductor substrate 110. The modified portion P may act as a crack site in which cracks CR may occur due to external physical shocks.

Referring to FIG. 19, a non-active surface 110B of a semiconductor substrate 110 may be polished using a polishing device, to reduce a thickness of the semiconductor substrate 110 and propagate a crack CR from a modified portion P. The polishing device may include a grinder. The grinder may move while rotating, and a polishing pad may be attached to a lower portion of the grinder. The polished semiconductor substrate 110 may have a second thickness T2, smaller than a first thickness T1 (see FIG. 18). For example, the second thickness T2 may be about 20 μm to about 100 μm. The semiconductor substrate 110 may be polished to have a desired second thickness T2 using the polishing device. At the same time, the crack CR in a peripheral region 104 may start from the modified portion P, may pass through an active surface 110F of the polished semiconductor substrate 110, and may spread to the peripheral region 104 of a device layer 120. According to some example embodiments, a laser may be irradiated into the semiconductor substrate 110 to form the modified portion P along the peripheral region 104 of the wafer structure 100W, and polish then the non-active surface 110B of the semiconductor substrate 110. The polishing process may be a grinding process under a state in which physical pressure is applied to the semiconductor substrate 110. When a polishing process is performed under a state in which physical pressure is applied to the semiconductor substrate 110, the polished semiconductor substrate 110 may be brittle and fractured. The brittle fracture refers to destruction without permanent deformation when a force exceeding an elastic limit is applied to an object. Therefore, while polishing the non-active surface 110B of the semiconductor substrate 110, the increasingly thinner semiconductor substrate 110 may be brittlely fractured by the crack CR propagating from the modified portion P. Since the crack CR propagating from the modified portion P may be formed along the peripheral region 104 isolating integrated circuit regions (102), the die regions 102 may be separated into individual semiconductor chips by brittle fracture of the semiconductor substrate 110. The separated semiconductor chip may be fixed by a protective sheet 200 without being moved from an original position thereof. In this operation, the polishing process may be performed such that a recess hole RH, previously formed, is exposed. Therefore, each of the semiconductor chips may have a structure including a trench on one side surface.

In some example embodiments, a cutting process is illustrated and explained as using a laser irradiation device 300, but the cutting process is not limited thereto. For example, the cutting process may be performed using a blade. Even in this case, the subsequent polishing process may be performed to expose the recess hole RH, allowing the semiconductor chip to include a trench.

Depending on some example embodiments, when the recess hole RH is not formed in a previous operation, a trench may be formed by removing a portion of one side surface of an individual semiconductor chip after the polishing process.

According to some example embodiments, a semiconductor chip having a structure including a side surface in which at least one side surface is recessed, may be introduced to provide a semiconductor chip having improved reliability and a semiconductor package including the same.

Various advantages and effects of the present inventive concepts are not limited to the above-described contents, and can be more easily understood through description of specific example embodiments.

While some example embodiments have been illustrated and described above, it will be apparent to those skilled in the art that modifications and variations could be made without departing from the scope of the present inventive concepts as defined by the appended claims.

What is claimed:

1. A semiconductor chip comprising:
a semiconductor substrate including a die region and a peripheral region surrounding the die region;
a device layer on the die region, the device layer including semiconductor devices and wiring layers;
a peripheral protective layer surrounding the device layer on the peripheral region; and
connection pads on an upper surface of the device layer and adjacent to one side of the upper surface of the device layer,
wherein a side surface of the semiconductor substrate adjacent to the one side of the upper surface of the device layer includes protruding portions located at both corners and a recess surface indented into the die region between the protruding portions.

2. The semiconductor chip of claim 1, wherein
the peripheral protective layer includes a first film surrounding the device layer on the semiconductor substrate,
a second film surrounding the device layer on the first film, and
the second film includes a material, different from a material of the first film.

3. The semiconductor chip of claim 2, wherein the first film includes the material having a thermal expansion coefficient higher than a thermal expansion coefficient of a material of the semiconductor substrate.

4. The semiconductor chip of claim 3, wherein the first film includes an organic compound.

5. The semiconductor chip of claim 2, wherein the second film includes the material having a thermal expansion coefficient lower than a thermal expansion coefficient of a material of the semiconductor substrate.

6. The semiconductor chip of claim 5, wherein the second film includes silicon oxide.

7. The semiconductor chip of claim 2, wherein the second film covers a portion of an upper surface of the first film, adjacent to the device layer, the second film exposing an edge portion of the upper surface of the first film.

8. The semiconductor chip of claim 7, further comprising:
residual alignment keys in an edge corner portion of the upper surface of the first film.

9. The semiconductor chip of claim 1, wherein an upper surface of the peripheral protective layer is on a level lower than a level of the upper surface of the device layer.

10. The semiconductor chip of claim 1, wherein a distance at which the recess surface is indented toward the die region is 5 μm to 30 μm.

11. The semiconductor chip of claim 1, wherein
the device layer further includes an interlayer insulating layer covering the semiconductor devices on the die region and an upper insulating layer covering the wiring layers on the interlayer insulating layer, and
the peripheral protective layer includes a material, and the material in the peripheral protective layer is different from a material of the interlayer insulating layer and a material of the upper insulating layer.

12. The semiconductor chip of claim 1, wherein a distance on a plane between the die region and the recess surface is 5 μm to 30 μm.

13. The semiconductor chip of claim 1, wherein a width of the peripheral region is 5 μm to 50 μm.

14. A semiconductor chip comprising:
a semiconductor substrate including an active surface and a non-active surface opposite to each other;
a device layer on the active surface and having a rectangular parallelepiped shape;
a peripheral protective layer surrounding the device layer on the active surface, the peripheral protective layer including a first film on the active surface and a second film on the first film; and
connection pads adjacent to one side surface of the device layer on an upper surface of the device layer,
wherein the first film has a first plane thickness between at least one side surface of the first film and at least one side surface of the device layer, and the first film surrounds the device layer, and
at least a portion of the first film, covering the one side surface of the device layer, has a second plane thickness, between a side surface of the first film and a side surface of the device layer smaller than the first plane thickness.

15. The semiconductor chip of claim 14, wherein the portion of the first film having the second plane thickness extends along the one side surface of the device layer.

16. The semiconductor chip of claim 14, wherein the second film has a surface area smaller than a surface area of the first film.

17. A semiconductor chip comprising:
a semiconductor substrate having an active surface and a non-active surface opposite to each other, the semiconductor substrate including side surfaces;
a device layer on the active surface, the device layer including semiconductor devices and wiring layers; and
a peripheral protective layer surrounding the device layer on the active surface,
wherein at least one of the side surfaces of the semiconductor substrate has protruding surfaces intersecting the other side surfaces of the semiconductor substrate at both corners, a recess surface indented toward the device layer between the protruding surfaces, and stepped surfaces connecting the protruding surfaces and the recess surface.

18. The semiconductor chip of claim 17, further comprising:
connection pads on one side of an upper surface of the device layer adjacent to the recess surface.

19. The semiconductor chip of claim 17, wherein
the device layer covers a portion of the active surface, and
the peripheral protective layer covers a remaining portion of the active surface, and
side surfaces of the peripheral protective layer are coplanar with the side surfaces of the semiconductor substrate.

20. The semiconductor chip of claim 17, further comprising:
residual alignment keys in a corner portion of an upper surface of the peripheral protective layer.
